(19) United States
(12) Patent Application Publication
(10) Pub. No.: US 2011/0298023 A1
(43) Pub. Date: Dec. 8, 2011

(54) SOLID-STATE IMAGING DEVICE

(75) Inventor: Tatsuya Ohguro, Kanagawa (JP)

(73) Assignee: KABUSHIKI KAISHA TOSHIBA, Tokyo (JP)

(21) Appl. No.: 13/154,579

(22) Filed: Jun. 7, 2011

(30) Foreign Application Priority Data
Jun. 7, 2010 (JP) 2010-130440

(51) Int. Cl. H01L 27/146

(52) U.S. Cl. 257/291; 257/E27.13

(57) ABSTRACT

According to the embodiments, a solid-state imaging device is provided, which includes a first electrode film, a first photoelectric conversion film, a first conductive film, a dielectric film, a second photoelectric conversion film, and a second conductive film. The first photoelectric conversion film covers the surface and the side of the first electrode film. The first conductive film covers the light receiving surface and the side of the first photoelectric conversion film. The dielectric film covers a portion corresponding to the side of the first photoelectric conversion film in the first conductive film. The second photoelectric conversion film covers a main portion of a portion corresponding to the light receiving surface of the first photoelectric conversion film in the first conductive film. The second conductive film covers the light receiving surface and the side of the second photoelectric conversion film.

### CROSS-REFERENCE TO RELATED APPLICATIONS

This application is based upon and claims the benefit of priority from the prior Japanese Patent Application No. 2010-130440, filed on Jun. 7, 2010; the entire contents of which are incorporated herein by reference.

### FIELD

Embodiments described herein relate generally to a solid-state imaging device.

### BACKGROUND

There is proposed a solid-state imaging device in which organic films for red, green, and blue are sequentially stacked as photoelectric conversion films over a semiconductor substrate where a transistor is formed. In this structure, the organic films for blue, green, and red selectively absorb light in wavelength bands of blue, green, and red in received light, photoelectrically convert them, and generate carriers, respectively. Therefore, when providing a predetermined number of pixels (photoelectric conversion films or photoelectric conversion portions) for respective colors (blue, green, and red) in a predetermined area, a light receiving area per pixel is easily increased.

In this structure, the side of each of the photoelectric conversion films for blue, green, and red is exposed. When the photoelectric conversion film is exposed to moisture or oxygen in an ambient atmosphere as above, the characteristics of the photoelectric conversion film tend to degrade.

### BRIEF DESCRIPTION OF THE DRAWINGS

FIG. 1A and FIG. 1B are diagrams illustrating a configuration of a solid-state imaging device according to a first embodiment;

FIG. 2A to FIG. 4F are diagrams illustrating a manufacturing method of the solid-state imaging device according to the first embodiment;

FIG. 5A to FIG. 6B are diagrams illustrating a manufacturing method of a solid-state imaging device according to a second embodiment;

FIG. 7A and FIG. 7B are diagrams illustrating a configuration of a solid-state imaging device according to a third embodiment;

FIG. 8A to FIG. 8D are diagrams illustrating a manufacturing method of the solid-state imaging device according to the third embodiment;

FIG. 9A to FIG. 9E are diagrams illustrating an operation of a solid-state imaging device according to a fourth embodiment;

FIG. 10A to FIG. 10E are diagrams illustrating a configuration of a solid-state imaging device according to a comparison example; and

FIG. 11 is a diagram illustrating a relationship between a composition of SiON and transparency.

### DETAILED DESCRIPTION

In general, according to one embodiment, a solid-state imaging device is provided, which includes a first electrode film, a first photoelectric conversion film, a first conductive film, a dielectric film, a second photoelectric conversion film, and a second conductive film. The first photoelectric conversion film covers the surface and the side of the first electrode film. The first conductive film covers the light receiving surface and the side of the first photoelectric conversion film. The dielectric film covers a portion corresponding to the side of the first photoelectric conversion film in the first conductive film. The second photoelectric conversion film covers a main portion of a portion corresponding to the light receiving surface of the first photoelectric conversion film in the first conductive film. The second conductive film covers the light receiving surface and the side of the second photoelectric conversion film.

Exemplary embodiments of a solid-state imaging device will be explained below in detail with reference to the accompanying drawings. The present invention is not limited to the following embodiments.

### First Embodiment

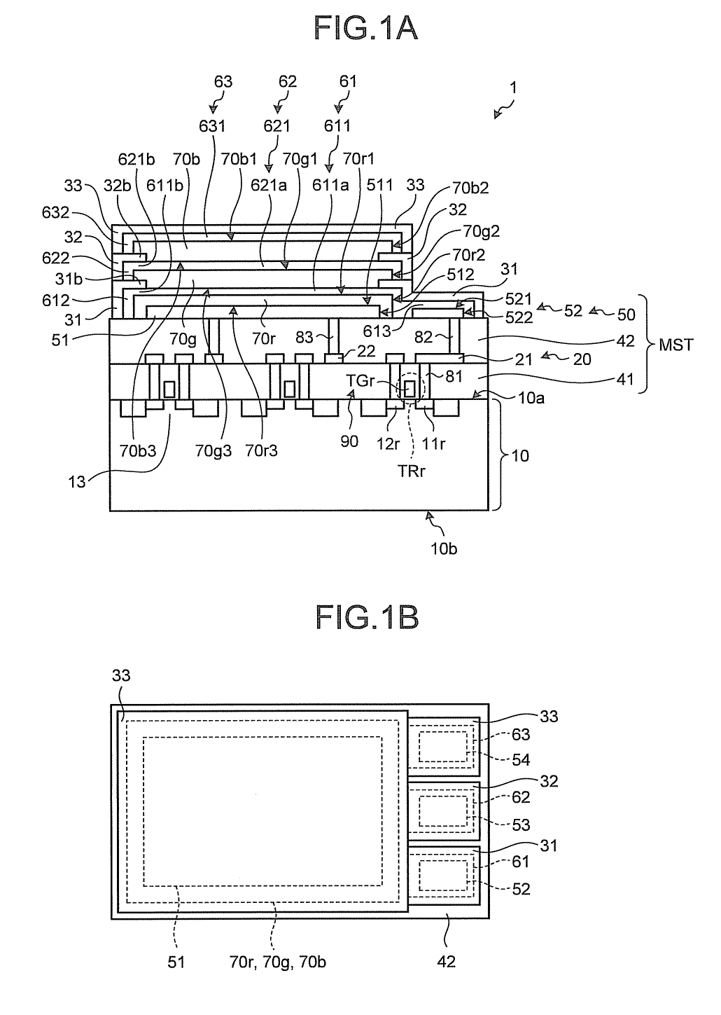

A configuration of a solid-state imaging device 1 according to the first embodiment is explained with reference to FIG. 1A and FIG. 1B. FIG. 1A is a cross-sectional view illustrating a cross-sectional configuration of the solid-state imaging device 1. FIG. 1B is a plan view illustrating a layout configuration of the solid-state imaging device 1.

The solid-state imaging device 1 includes a semiconductor substrate 10, a multi-layer interconnection structure MST, a photoelectric conversion film (first photoelectric conversion film) 70r, a conductive film (first conductive film) 61, a dielectric film 31, a photoelectric conversion film (second photoelectric conversion film) 70g, a conductive film (second conductive film) 62, a dielectric film (second dielectric film) 32, a photoelectric conversion film (third photoelectric conversion film) 70b, a conductive film (third conductive film) 63, and a dielectric film 33.

In the semiconductor substrate 10, for example, a semiconductor region 11r and a semiconductor region 12r are arranged in a well region 13. The well region 13 is formed of semiconductor (for example, silicon) that contains first conductivity-type (for example, P-type) impurities at a low concentration. The P-type impurities are boron, for example. The semiconductor region 11r and the semiconductor region 12r are formed of semiconductor (for example, silicon) that contains second conductivity-type (for example, N-type) impurities at a concentration higher than the concentration of the first conductivity-type impurities in the well region 13. The second conductivity type is a conductivity type opposite to the first conductivity type. The N-type impurities are phosphorus or arsenic, for example.

The multi-layer interconnection structure MST is arranged on the semiconductor substrate 10. The multi-layer interconnection structure MST has a structure in which a wiring layer and a dielectric layer are alternately stacked a plurality of times. In the multi-layer interconnection structure MST, for example, a wiring layer 90, a dielectric layer 41, a wiring layer 20, a dielectric layer 42, and a wiring layer 50 are sequentially stacked.

The wiring layer 90 is arranged on the semiconductor substrate 10. The wiring layer 90 is, for example, formed of polysilicon. The wiring layer 90, for example, includes a gate electrode TGr, other gate electrodes, and the like. The gate electrode TGr is arranged between the semiconductor region 11r and the semiconductor region 12r on the semiconductor substrate 10, whereby a transistor TRr is configured.

The dielectric layer 41 covers the semiconductor substrate 10, the gate electrode TGr, and the like. The dielectric layer 41 is, for example, formed of silicon oxide. The wiring layer 20 is arranged on the dielectric layer 41. The wiring layer 20 is, for example, formed of metal whose main component is Al, Ti, Cu, or the like. The wiring layer 20, for example, includes an electrode film 21 and an electrode film 22. The electrode film 21 is connected to the semiconductor region 11r via a contact plug 81. The contact plug 81 penetrates through the dielectric layer 41 to connect the electrode film 21 with the semiconductor region 11r.

The dielectric layer 42 covers the dielectric layer 41 and the wiring layer 20. The dielectric layer 42 is the uppermost dielectric layer in the multi-layer interconnection structure MST. The dielectric layer 42 is, for example, formed of silicon oxide. The wiring layer 50 is arranged on the dielectric layer 42. The wiring layer 50 is the uppermost wiring layer in the multi-layer interconnection structure MST. The wiring layer 50 is, for example, formed of metal whose main component is Al, Ti, Cu, or the like. The wiring layer 50, for example, includes an electrode film (first electrode film) 51, an electrode film (second electrode film) 52, an electrode film (third electrode film) 53, and an electrode film (fourth electrode film) 54. The electrode film 51, the electrode film 52, the electrode film 53, and the electrode film 54 are separated from one another in the wiring layer 50.

The electrode film 51 covers part of the surface of the dielectric layer 42. Specifically, the electrode film 51 covers the surface of the dielectric layer 42 at a position adjacent to the electrode film 52, the electrode film 53, and the electrode film 54. Moreover, a surface 511 and sides 512 of the electrode film 51 are covered by the photoelectric conversion film 70r. With this structure, the electrode film 51 is electrically connected to a surface 70r3 on the opposite side of a light receiving surface 70r1 of the photoelectric conversion film 70r. Moreover, the electrode film 51 has a pattern included in the photoelectric conversion film 70r when visualized from a direction vertical to the surface 511 (see FIG. 18). The electrode film 51 is, for example, connected to the electrode film 22 via a contact plug 83.

The electrode film 52 covers the surface of the dielectric layer 42 at a position adjacent to the electrode film 51, the photoelectric conversion film 70r, and the electrode film 53. The electrode film 52, for example, covers the dielectric layer 42 on the opposite side of the electrode film 54 across the electrode film 53. Moreover, a surface 521 and sides 522 of the electrode film 52 are covered by the conductive film 61 (see FIG. 1B). With this structure, the electrode film 52 is electrically connected to the light receiving surface 70r1 of the photoelectric conversion film 70r and a surface 70g3 of the photoelectric conversion film 70g via the conductive film 61. Moreover, the electrode film 52 has a pattern included in the conductive film 61 when visualized from a direction vertical to the surface 521. The electrode film 52 is, for example, connected to the electrode film 21 via a contact plug 82.

The electrode film 53 covers the dielectric layer 42 at a position adjacent to the electrode film 51, the photoelectric conversion film 70r, the electrode film 52, and the electrode film 54. The electrode film 53, for example, covers the dielectric layer 42 between the electrode film 52 and the electrode film 54. Moreover, the surface and the sides of the electrode film 53 are covered by the conductive film 62 (see FIG. 1B). With this structure, the electrode film 53 is electrically connected to a light receiving surface 70g1 of the photoelectric conversion film 70g and a surface 70b3 of the photoelectric conversion film 70b via the conductive film 62. Moreover, the electrode film 53 has a pattern included in the conductive film 62 when visualized from a direction vertical to the surface of the electrode film 53. The electrode film 53 is, for example, connected to an electrode film (not shown) via a contact plug (not shown).

The electrode film 54 covers the dielectric layer 42 at a position adjacent to the electrode film 51, the photoelectric conversion film 70r, and the electrode film 53. The electrode film 54, for example, covers the dielectric layer 42 on the opposite side of the electrode film 52 across the electrode film 53. Moreover, the surface and the sides of the electrode film 54 are covered by the conductive film 63 (see FIG. 1B). With this structure, the electrode film 54 is electrically connected to a light receiving surface 70b1 of the photoelectric conversion film 70b via the conductive film 63. Moreover, the electrode film 54 has a pattern included in the conductive film 63 when visualized from a direction vertical to the surface of the electrode film 54. The electrode film 54 is, for example, connected to an electrode film (not shown) via a contact plug (not shown).

The photoelectric conversion film 70r covers the surface 511 and the sides 512 of the electrode film 51 and further covers the dielectric layer 42 around the electrode film 51. With this structure, the surface 70r3 on the opposite side of the light receiving surface 70r1 of the photoelectric conversion film 70r is electrically connected to the electrode film 51. The photoelectric conversion film 70r is, for example, formed as an island-like pattern with a dimension equal to or larger than a lower limit capable of being formed by vapor deposition using a metal mask to be described later. The photoelectric conversion film 70r absorbs light in the red wavelength region in received light and generates charges corresponding to the absorbed light. The photoelectric conversion film 70r is, for example, an organic photoelectric conversion film, and formed of an organic material having a property in which light in the red wavelength region is absorbed and light in other wavelength regions is transmitted.

The conductive film 61 covers the light receiving surface 70r1 and sides 70r2 of the photoelectric conversion film 70r. The conductive film 61 continuously extends from the photoelectric conversion film 70r to the electrode film 52 and covers the surface 521 and the sides 522 of the electrode film 52. With this structure, the light receiving surface 70r1 and the sides 70r2 of the photoelectric conversion film 70r are electrically connected to the electrode film 52. The conductive film 61 is, for example, formed of a transparent conductive material such as ITO, TiO₂, MgO, or ZnO.

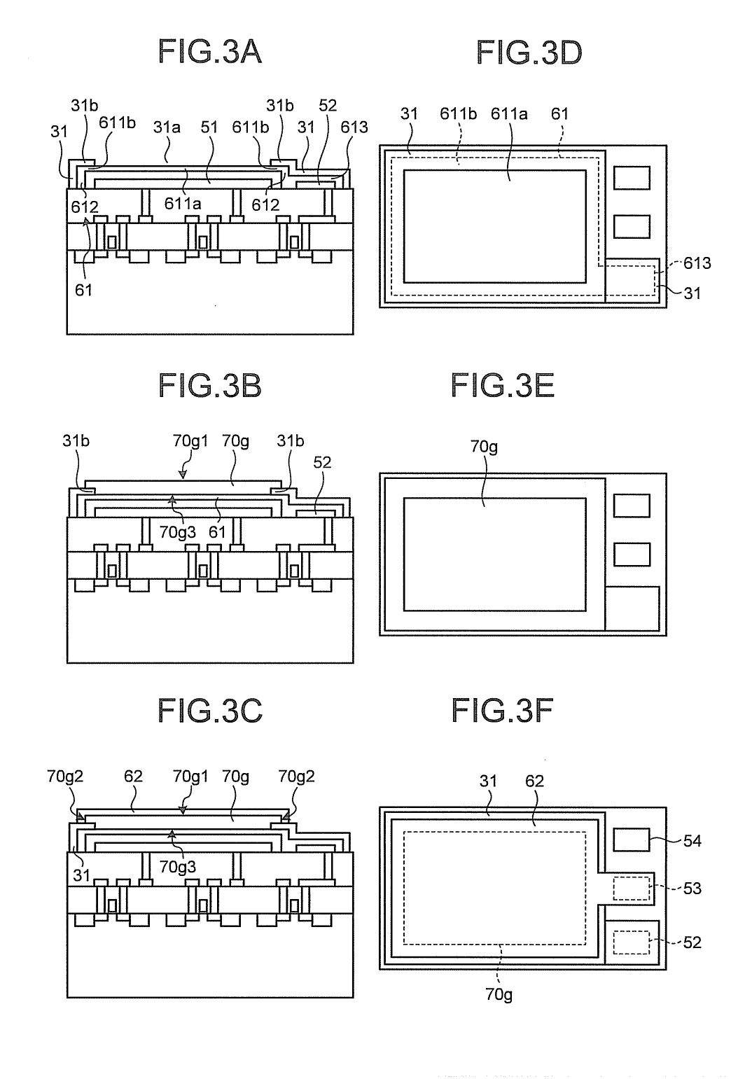

The conductive film 61 includes a portion 611 corresponding to the light receiving surface 70r1 of the photoelectric conversion film 70r and a portion 612 corresponding to the sides 70r2 of the photoelectric conversion film 70r. The portion 611 corresponding to the light receiving surface 70r1 includes a main portion 611a included inside the photoelectric conversion film 70r when visualized from a direction vertical to the light receiving surface 70r1, and a peripheral portion 611b positioned around the main portion 611a when visualized from a direction vertical to the light receiving surface 70r1 (see FIG. 3D). The main portion 611a is covered by the photoelectric conversion film 70g. Therefore, the surface 70g3 on the opposite side of the light receiving surface 70g1 of the photoelectric conversion film 70g is electrically connected to the electrode film 52. The peripheral portion 611b and the portion 612 are covered by the dielectric film 31.

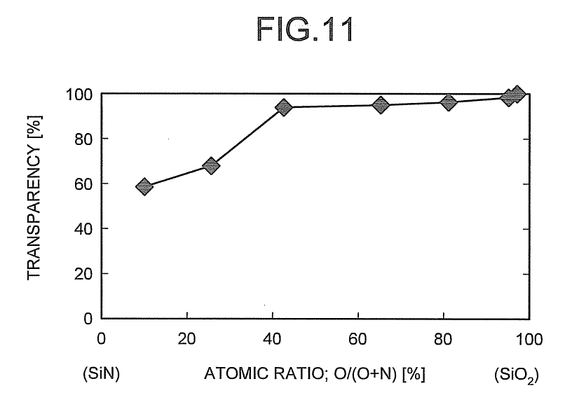

The dielectric film 31 covers the peripheral portion 611b and the portion 612 of the conductive film 61 without covering the main portion 611a of the conductive film 61. With this structure, the conductive film 61 and the conductive film 62 are insulated from each other. The dielectric film 31 has an opening 31a (see FIG. 3A) corresponding to the main portion 611a. Moreover, the dielectric film 31 covers a portion 613 corresponding to the electrode film 52 in the conductive film 61. With this structure, the electrode film 52 and the electrode film 53 are insulated from each other. The dielectric film 31 is, for example, formed of SiON. At this time, the composition of SiON can be adjusted to suppress attenuation of incident light by the dielectric film 31 (SiON film). For example, for setting the transparency of the dielectric film 31 (SiON film) to 95% or more, the composition is adjusted so that the O/(O+N) ratio of SiON becomes 40% or more (see FIG. 11).

The photoelectric conversion film 70g covers the main portion 611a included inside the photoelectric conversion film 70r in the portion 611 of the conductive film 61 when visualized from a direction vertical to the light receiving surface 70r1. Therefore, the surface 70g3 on the opposite side of the light receiving surface 70g1 of the photoelectric conversion film 70g is electrically connected to the electrode film 52 via the conductive film 61. The photoelectric conversion film 70g further covers a portion 31b corresponding to the peripheral portion 611b of the conductive film 61 in the dielectric film 31. The photoelectric conversion film 70g is, for example, formed as an island-like pattern with a dimension equal to or larger than a lower limit capable of being formed by vapor deposition using a metal mask to be described later. The photoelectric conversion film 70g absorbs light in the green wavelength region in received light and generates charges corresponding to the absorbed light. The photoelectric conversion film 70g is, for example, an organic photoelectric conversion film, and formed of an organic material having a property in which light in the green wavelength region is absorbed and light in other wavelength regions is transmitted.

The conductive film 62 covers the light receiving surface 70g1 and sides 70g2 of the photoelectric conversion film 70g. The conductive film 62 continuously extends from the photoelectric conversion film 70g to the electrode film 53 and covers the surface and the sides of the electrode film 53. Therefore, the light receiving surface 70g1 and the sides 70g2 of the photoelectric conversion film 70g are electrically connected to the electrode film 53. The conductive film 62 is, for example, formed of a transparent conductive material such as ITO, TiO₂, MgO, or ZnO.

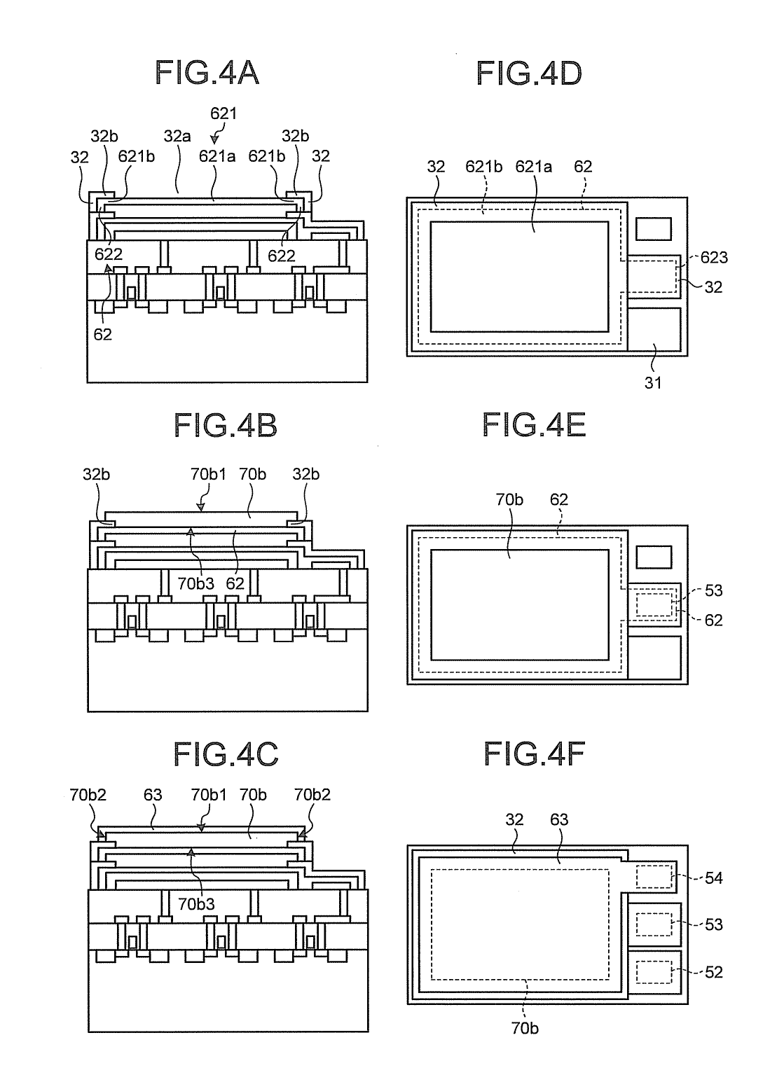

The conductive film 62 includes a portion 621 corresponding to the light receiving surface 70g1 of the photoelectric conversion film 70g and a portion 622 corresponding to the sides 70g2 of the photoelectric conversion film 70g. The portion 621 corresponding to the light receiving surface 70g1 includes a main portion 621a included inside the photoelectric conversion film 70g when visualized from a direction vertical to the light receiving surface 70g1 and a peripheral portion 621b positioned around the main portion 621a when visualized from a direction vertical to the light receiving surface 70g1 (see FIG. 4D). The main portion 621a is covered by the photoelectric conversion film 70b. Therefore, the surface 70b3 on the opposite side of the light receiving surface 70b1 of the photoelectric conversion film 70b is electrically connected to the electrode film 53. The peripheral portion 621b and the portion 622 are covered by the dielectric film 32.

The dielectric film 32 covers the peripheral portion 621b and the portion 622 of the conductive film 62 without covering the main portion 621a of the conductive film 62. With this structure, the conductive film 62 and the conductive film 63 are insulated from each other. The dielectric film 32 has an opening 32a (see FIG. 4A) corresponding to the main portion 621a. Moreover, the dielectric film 32 covers a portion corresponding to the electrode film 53 in the conductive film 62. With this structure, the electrode film 53 and the electrode film 54 are insulated from each other. The dielectric film 32 is, for example, formed of SiON. At this time, the composition of SiON can be adjusted to suppress attenuation of incident light by the dielectric film 32 (SiON film). For example, for setting the transparency of the dielectric film 32 (SiON film) to 95% or more, the composition is adjusted so that the O/(O+N) ratio of SiON becomes 40% or more (see FIG. 11).

The photoelectric conversion film 70b covers the main portion 621a included inside the photoelectric conversion film 70g in the portion 621 of the conductive film 62 when visualized from a direction vertical to the light receiving surface 70g1. With this structure, the surface 70b3 on the opposite side of the light receiving surface 70b1 of the photoelectric conversion film 70b is electrically connected to the electrode film 53 via the conductive film 62. The photoelectric conversion film 70b further covers a portion 32b corresponding to the peripheral portion 621b of the conductive film 62 in the dielectric film 32. The photoelectric conversion film 70b is, for example, formed as an island-like pattern with a dimension equal to or larger than a lower limit capable of being formed by vapor deposition using a metal mask to be described later. The photoelectric conversion film 70b absorbs light in the blue wavelength region in received light and generates charges corresponding to the absorbed light. The photoelectric conversion film 70b is, for example, an organic photoelectric conversion film, and formed of an organic material having a property in which light in the blue wavelength region is absorbed and light in other wavelength regions is transmitted.

The conductive film 63 covers the light receiving surface 70b1 and sides 70b2 of the photoelectric conversion film 70b. The conductive film 63 continuously extends from the photoelectric conversion film 70b to the electrode film 54 and covers the surface and the sides of the electrode film 54. With this structure, the light receiving surface 70b1 and the sides 70b2 of the photoelectric conversion film 70b are electrically connected to the electrode film 54. The conductive film 63 is, for example, formed of a transparent conductive material such as ITO, TiO₂, MgO, or ZnO.

The conductive film 63 includes a portion 631 corresponding to the light receiving surface 70b1 of the photoelectric conversion film 70b and a portion 632 corresponding to the sides 70b2 of the photoelectric conversion film 70b. The portion 631 and the portion 632 are covered by the dielectric film 33.

The dielectric film 33 covers the portion 631 and the portion 632 of the conductive film 63. Moreover, the dielectric film 33 covers a portion corresponding to the electrode film 54 in the conductive film 63. The dielectric film 33, is, for example, formed of SiON. At this time, the composition of SiON can be adjusted to suppress attenuation of incident light by the dielectric film 33 (SiON film). For example, for setting the transparency of the dielectric film 33 (SiON film) to 95% or more, the composition is adjusted so that the O/(O+N) ratio of SiON becomes 40% or more (see FIG. 11).

All of the surfaces of all of the photoelectric conversion films 70r, 70g, and 70r are covered by predetermined films so as not to be exposed. Each of the photoelectric conversion films 70r, 70g, and 70b is formed as an island-like pattern with no contact hole.

Moreover, each of the electrode film 51, the electrode film 52, the electrode film 53, and the electrode film 54 covers the uppermost dielectric layer 42 in the multi-layer interconnection structure MST and has an even height from a surface 10a of the semiconductor substrate 10. The electrode film 52 functions both as an electrode on the light receiving surface 70r1 side of the photoelectric conversion film 70r and as an electrode on the surface 70g3 side of the photoelectric conversion film 70g. The electrode film 53 functions both as an electrode on the light receiving surface 70g1 side of the photoelectric conversion film 70g and as an electrode on the surface 70b3 side of the photoelectric conversion film 70b are shared.

Next, the operation of the solid-state imaging device 1 according to the first embodiment is explained. In the following, explanation is given for the operation in the case where a bias is applied to the photoelectric conversion film 70r via the electrode film 51 as an example.

When the bias is applied, a signal corresponding to charges generated in the photoelectric conversion film 70r is transferred to the electrode film 52 via the conductive film 61. The signal transferred to the electrode film 52 is further transferred to the semiconductor region hr via the contact plug 82, the electrode film 21, and the contact plug 81. The semiconductor region hr converts the transferred signal (voltage) into charges and stores the charges. The transistor TRr is turned on when a control signal in an active level is supplied to the gate electrode TGr. Consequently, the transistor TRr transfers the charges in the semiconductor region hr to the semiconductor region 12r. The semiconductor region 12r converts the transferred charges into a voltage. A not-shown amplifying transistor outputs a signal corresponding to the converted voltage to a signal line. The signal (analog signal) output to the signal line is, for example, converted into a digital signal by an A/D conversion circuit (not shown) in the solid-state imaging device 1 or in its subsequent stage to be, for example, an image signal for red. In the similar manner, signals of semiconductor regions 11g and 11b are read out and converted into digital signals to be image signals for green and blue, respectively. Then, predetermined image processing is performed on the image signal for each color, which is read out from each of a plurality of two-dimensionally arranged pixels and is converted, in an image processing circuit (not shown) in the subsequent stage, thereby obtaining image data.

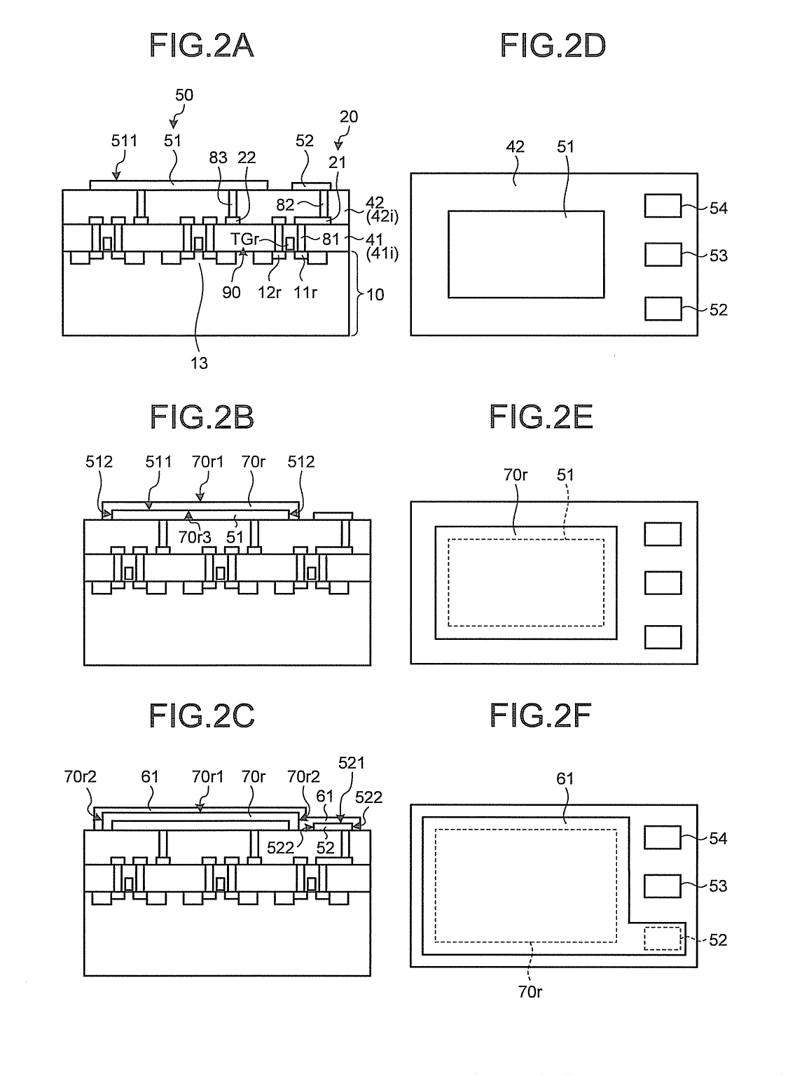

Next, the manufacturing method of the solid-state imaging device 1 according to the first embodiment is explained with reference to FIG. 2A to FIG. 4F, FIG. 1A, and FIG. 1B. FIG. 2A to FIG. 2C, FIG. 3A to FIG. 3C, and FIG. 4A to FIG. 4C are process cross-sectional views illustrating the manufacturing method of the solid-state imaging device 1. FIG. 2D to FIG. 2F, FIG. 3D to FIG. 3F, and FIG. 4D to FIG. 4F are plan views corresponding to FIG. 2A to FIG. 2C, FIG. 3A to FIG. 3C, and FIG. 4A to FIG. 4C, respectively. FIG. 1A and FIG. 1B are used as a process cross-sectional view and a plan view corresponding thereto, respectively.

In the process shown in FIG. 2A and FIG. 2D, the semiconductor regions hr and 12r and other semiconductor regions are formed in the well region 13 of the semiconductor substrate 10 by an ion implantation method or the like. The well region 13 is formed of semiconductor (for example, silicon) that contains first conductivity-type (for example, P-type) impurities at a low concentration. The semiconductor regions hr and 12r are formed, for example, by implanting second conductivity-type (for example, N-type) impurities in the well region 13 of the semiconductor substrate 10 at a concentration higher than the concentration of the first conductivity-type impurities in the well region 13. The second conductivity type is a conductivity type opposite to the first conductivity type.

Then, the multi-layer interconnection structure MST is formed on the semiconductor substrate 10.

Specifically, the pattern of the wiring layer 90 including the gate electrode TGr, other gate electrodes, and the like is formed of, for example, polysilicon. Then, a dielectric layer 41i that covers the semiconductor substrate 10 and the wiring layer 90 is formed of, for example, silicon oxide. Moreover, for example, the contact plug 81 that penetrates through the dielectric layer 41 and is connected to the semiconductor region hr is formed of, for example, a conductive material such as tungsten.

Thereafter, the pattern of the wiring layer 20 including the electrode film 21, the electrode film 22, and the like is formed of, for example, metal whose main component is Al, Ti, Cu, or the like, on the dielectric layer 41. Then, a dielectric layer 42i that covers the dielectric layer 41 and the wiring layer 20 is formed of, for example, silicon oxide. Moreover, for example, the contact plugs 82 and 83 that penetrate through the dielectric layer 42 and are connected to the electrode films 21 and 22, respectively, are formed of, for example, a conductive material such as tungsten.

Then, a metal layer (not shown) is formed on the entire surface of the dielectric layer 42 by a sputtering method or the like. The metal layer is formed of, for example, metal (for example, TiN) whose main component is Al, Ti, Cu, or the like. The metal layer is formed to have a film thickness of, for example, about 50 nm or less. The metal layer is patterned by a lithography, a dry etching, and the like to form the wiring layer 50 including the electrode film 51, the electrode film 52, the electrode film 53, and the electrode film 54. The electrode film 51, the electrode film 52, the electrode film 53, and the electrode film 54 are formed as island-like patterns separated from one another. The electrode film 51 is formed of a pattern corresponding to the photoelectric conversion film 70r to be formed, that is, a pattern to be included in the photoelectric conversion film 70r when visualized from a direction vertical to the surface 511 of the electrode film 51. Each of the electrode film 52, the electrode film 53, and the electrode film 54 is formed at a position adjacent to the electrode film 51.

In the process shown in FIG. 2B and FIG. 2E, the photoelectric conversion film 70r is formed to cover the surface 511 and the sides 512 of the electrode film 51. Specifically, the photoelectric conversion film 70r is formed by plating or vapor deposition using a metal mask having an opening of a size corresponding to a pattern to be formed (for example, approximately the same size as the pattern to be formed). The photoelectric conversion film 70r is, for example, formed of an organic material having a property in which light in the red wavelength region is absorbed and light in other wavelength regions is transmitted. The photoelectric conversion film 70r is formed of a pattern that includes the electrode film 51 when visualized from a direction vertical to the surface 511 of the electrode film 51 (see FIG. 2E). Therefore, the photoelectric conversion film 70r covers the surface 511 and the sides 512 of the electrode film 51. Moreover, the surface 70r3 on the opposite side of the light receiving surface 70r1 of the photoelectric conversion film 70r is electrically connected to the electrode film 51. The horizontal and vertical size of the opening in the metal mask is, for example, a predetermined value or more and 1.2 μm or less. The film thickness of the deposited photoelectric conversion film 70r is, for example, a predetermined value or more and 1 μm or less.

In the process shown in FIG. 2C and FIG. 2F, the conductive film 61 is formed to cover the light receiving surface 70r1 and the sides 70r2 of the photoelectric conversion film 70r and the surface 521 and the sides 522 of the electrode film 52. Specifically, a conductive layer (not shown) is formed on the entire surface by a sputtering method or the like. The conductive layer is, for example, formed of a transparent conductive material such as ITO, TiO₂, MgO, or ZnO. The conductive layer is patterned by a lithography and an etching to form the conductive film 61. The conductive film 61 is formed of a pattern that includes both the photoelectric conversion film 70r and the electrode film 52 and does not overlap with any of the electrode film 53 and the electrode film 54 when visualized from a direction vertical to the light receiving surface 70r1 of the photoelectric conversion film 70r (see FIG. 2F). Therefore, the conductive film 61 covers the light receiving surface 70r1 and the sides 70r2 of the photoelectric conversion film 70r. The conductive film 61 is formed as a continuous pattern from the photoelectric conversion film 70r to the electrode film 52. Therefore, the light receiving surface 70r1 of the photoelectric conversion film 70r is electrically connected to the electrode film 52.

In the process shown in FIG. 3A and FIG. 3D, the dielectric film 31 is formed to cover the conductive film 61 except the main portion 611a. Specifically, a dielectric layer (not shown) is formed on the entire surface by the CVD or the like. For example, the dielectric layer is formed of SiON whose composition is adjusted so that the O/(O+N) ratio becomes 40% or more. The dielectric film is patterned by a lithography, a dry etching, and the like to form the dielectric film 31. The dielectric film 31 is formed of a pattern in which a portion corresponding to the main portion 611a is excluded from a pattern including the conductive film 61 when visualized from a direction vertical to the light receiving surface 70r1 of the photoelectric conversion film 70r (see FIG. 3D).

Consequently, the opening 31a from which the main portion 611a of the conductive film 61 is exposed is formed in the dielectric film 31. For example, the opening 31a can be a pattern having a shape and size equal to the electrode film 51 when visualized from a direction vertical to the light receiving surface 70r1 of the photoelectric conversion film 70r. Moreover, the dielectric film 31 covers the portion 612 corresponding to the sides 70r2 of the photoelectric conversion film 70r in the conductive film 61 and further covers the peripheral portion 611b positioned around the main portion 611a in the portion 611 corresponding to the light receiving surface 70r1 of the photoelectric conversion film 70r in the conductive film 61. Moreover, the dielectric film 31 covers the portion 613 corresponding to the electrode film 52 in the conductive film 61.

In the process shown in FIG. 3B and FIG. 3E, the photoelectric conversion film 70g is formed to cover the exposed main portion 611a of the conductive film 61 and the portion 31b corresponding to the peripheral portion 611b of the conductive film 61 in the dielectric film 31. Specifically, the photoelectric conversion film 70g is formed by plating or vapor deposition using a metal mask having an opening of a size corresponding to a pattern to be formed (for example, approximately the same size as the pattern to be formed). The photoelectric conversion film 70g is formed of, for example, an organic material having a property in which light in the green wavelength region is absorbed and light in other wavelength regions is transmitted. The photoelectric conversion film 70g is, for example, formed of a pattern having a shape and size equal to the photoelectric conversion film 70r when visualized from a direction vertical to the light receiving surface 70r1 of the photoelectric conversion film 70r (see FIG. 3E). Consequently, the photoelectric conversion film 70g covers the exposed main portion 611a of the conductive film 61 and the portion 31b corresponding to the peripheral portion 611b of the conductive film 61 in the dielectric film 31. Moreover, the surface 70g3 on the opposite side of the light receiving surface 70g1 of the photoelectric conversion film 70g is electrically connected to the electrode film 52 via the conductive film 61. The horizontal and vertical size of the opening in the metal mask is, for example, a predetermined value or more and 1.2 μm or less. The film thickness of the deposited photoelectric conversion film 70g is, for example, a predetermined value or more and 1 μm or less.

In the process shown in FIG. 3C and FIG. 3F, the conductive film 62 is formed to cover the light receiving surface 70g1 and the sides 70g2 of the photoelectric conversion film 70g and the surface and the sides of the electrode film 53. Specifically, a conductive layer (not shown) is formed on the entire surface by a sputtering method or the like. The conductive layer is, for example, formed of a transparent conductive material such as ITO, TiO₂, MgO, or ZnO. The conductive layer is patterned by a lithography and an etching to form the conductive film 62. The conductive film 62 is formed of a pattern that includes both the photoelectric conversion film 70g and the electrode film 53 and does not overlap with any of the electrode film 52 and the electrode film 54 when visualized from a direction vertical to the light receiving surface 70g1 of the photoelectric conversion film 70g (see FIG. 3F). Therefore, the conductive film 62 covers the light receiving surface 70g1 and the sides 70g2 of the photoelectric conversion film 70g. The conductive film 62 is formed as a continuous pattern from the photoelectric conversion film 70g to the electrode film 53. Therefore, the light receiving surface 70g1 of the photoelectric conversion film 70g is electrically connected to the electrode film 53 via the conductive film 62.

In the process shown in FIG. 4A and FIG. 4D, the dielectric film 32 is formed to cover the conductive film 62 except the main portion 621a. Specifically, a dielectric layer (not shown) is formed on the entire surface by the CVD or the like. For example, the dielectric layer is formed of SiON whose composition is adjusted so that the O/(O+N) ratio becomes 40% or more. The dielectric film is patterned by a lithography, a dry etching, and the like to form the dielectric film 32. The dielectric film 32 is formed of a pattern in which a portion corresponding to the main portion 621a is excluded from a pattern including the conductive film 62 when visualized from a direction vertical to the light receiving surface 70g1 of the photoelectric conversion film 70g (see FIG. 4D).

Consequently, an opening 32a from which the main portion 621a of the conductive film 62 is exposed is formed in the dielectric film 32. For example, the opening 32a can be a pattern having a shape and size equal to the electrode film 51 when visualized from a direction vertical to the light receiving surface 70g1 of the photoelectric conversion film 70g. Moreover, the dielectric film 32 covers the portion 622 corresponding to the sides 70g2 of the photoelectric conversion film 70g in the conductive film 62 and further covers the peripheral portion 621b positioned around the main portion 621a in the portion 621 corresponding to the light receiving surface 70g1 of the photoelectric conversion film 70g in the conductive film 62. Moreover, the dielectric film 32 covers a portion 623 corresponding to the electrode film 53 in the conductive film 62 (see FIG. 4D).

In the process shown in FIG. 4B and FIG. 4E, the photoelectric conversion film 70b is formed to cover the exposed main portion 621a of the conductive film 62 and the portion 32b corresponding to the peripheral portion 621b of the conductive film 62 in the dielectric film 32. Specifically, the photoelectric conversion film 70b is formed by plating or vapor deposition using a metal mask having an opening of a size corresponding to a pattern to be formed (for example, approximately the same size as the pattern to be formed). The photoelectric conversion film 70b is formed of, for example, an organic material having a property in which light in the blue wavelength region is absorbed and light in other wavelength regions is transmitted. The photoelectric conversion film 70b is, for example, formed of a pattern having a shape and size equal to the photoelectric conversion film 70g when visualized from a direction vertical to the light receiving surface 70g1 of the photoelectric conversion film 70g (see FIG. 4E). Consequently, the photoelectric conversion film 70b covers the exposed main portion 621a of the conductive film 62 and the portion 32b corresponding to the peripheral portion 621b of the conductive film 62 in the dielectric film 32. Moreover, the surface 70b3 on the opposite side of the light receiving surface 70b1 of the photoelectric conversion film 70b is electrically connected to the electrode film 53 via the conductive film 62 (see FIG. 4E). The horizontal and vertical size of the opening in the metal mask is, for example, a predetermined value or more and 1.2 μm or less. The film thickness of the deposited photoelectric conversion film 70b is, for example, a predetermined value or more and 1 μm or less.

In the process shown in FIG. 4C and FIG. 4F, the conductive film 63 is formed to cover the light receiving surface 70b1 and the sides 70b2 of the photoelectric conversion film 70b and the surface and the sides of the electrode film 54. Specifically, a conductive layer (not shown) is formed on the entire surface by a sputtering method or the like. The conductive layer is, for example, formed of a transparent conductive material such as ITO, TiO₂, MgO, or ZnO. The conductive layer is patterned by a lithography and an etching to form the conductive film 63. The conductive film 63 is formed of a pattern that includes both the photoelectric conversion film 70b and the electrode film 54 and does not overlap with any of the electrode film 52 and the electrode film 53 when visualized from a direction vertical to the light receiving surface 70b1 of the photoelectric conversion film 70b (see FIG. 4F). Therefore, the conductive film 63 covers the light receiving surface 70b1 and the sides 70b2 of the photoelectric conversion film 70b. The conductive film 63 is formed as a continuous pattern from the photoelectric conversion film 70b to the electrode film 54. Therefore, the light receiving surface 70b1 of the photoelectric conversion film 70b is electrically connected to the electrode film 54 via the conductive film 63.

In the process shown in FIG. 1A and FIG. 1B, the dielectric film 33 is formed to cover the conductive film 63. Specifically, a dielectric layer (not shown) is formed on the entire surface by the CVD or the like. For example, the dielectric layer is formed of SiON whose composition is adjusted so that the O/(O+N) ratio becomes 40% or more. The dielectric layer is patterned by a lithography, a dry etching, and the like to form the dielectric film 33. The dielectric film 33 is formed of a pattern including the conductive film 63 when visualized from a direction vertical to the light receiving surface 70g1 of the photoelectric conversion film 70g (see FIG. 1B).

Consequently, the dielectric film 33 covers the portion 632 corresponding to the sides 70b2 of the photoelectric conversion film 70b in the conductive film 63 and further covers the portion 631 corresponding to the light receiving surface 70b1 of the photoelectric conversion film 70b in the conductive film 63. Moreover, the dielectric film 33 covers the portion corresponding to the electrode film 54 in the conductive film 63 (see FIG. 1B).

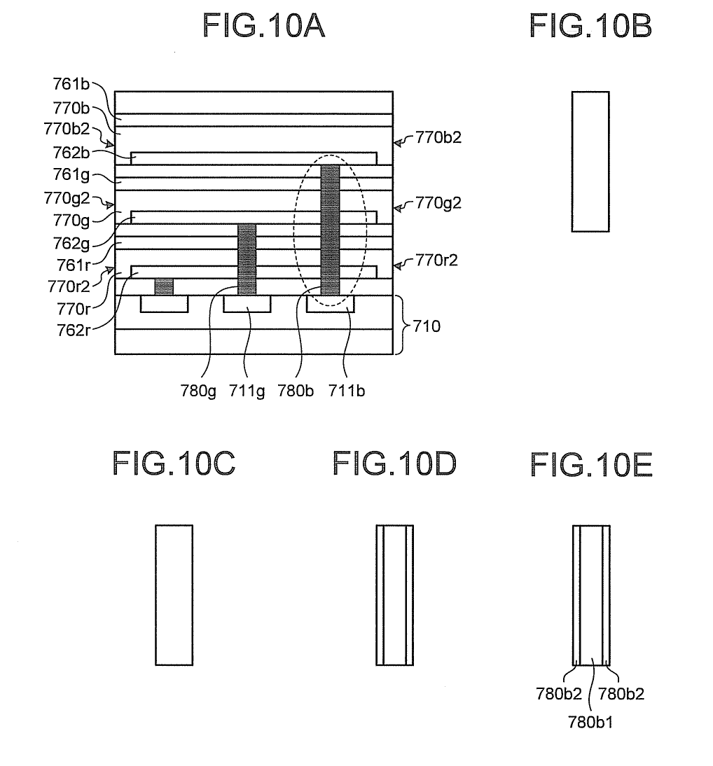

As shown in FIG. 10A, consider a case where a three photoelectric conversion films 770r, 770g, and 770b are simply stacked on a semiconductor substrate 710 in a solid-state imaging device 700. In the solid-state imaging device 700, sides 770r2, 770g2, and 770b2 of the respective photoelectric conversion films 770r, 770g, and 770b are exposed to the ambient atmosphere. For example, when the photoelectric conversion films 770r, 770g, and 770b are formed of an organic material, if the photoelectric conversion films 770r, 770g, and 770b are exposed to moisture or oxygen of the ambient atmosphere, the photoelectric conversion efficiency of the photoelectric conversion films 770r, 770g, and 770b tends to degrade. Moreover, if the photoelectric conversion films 770r, 770g, and 770b are exposed to moisture or oxygen of the ambient atmosphere, the photoelectric conversion films 770r, 770g, and 770b expand and the contact resistance with upper and lower electrode films 762r, 761r, 762g, 761g, 762b, and 761b tend to increase. As above, if the photoelectric conversion films 770r, 770g, and 770b are exposed to moisture or oxygen of the ambient atmosphere, the characteristics of the photoelectric conversion films 770r, 770g, and 770b tend to degrade.

On the contrary, in the first embodiment, the light receiving surfaces 70r1, 70g1, and 70b1, and the sides 70r2, 70g2, and 70b2 of the photoelectric conversion films 70r, 70g, and 70b are covered by the conductive films 61, 62, and 63, respectively. Therefore, each of the photoelectric conversion films 70r, 70g, and 70b is not easily exposed to moisture and oxygen of the ambient atmosphere. Thus, according to the first embodiment, degradation of the characteristics of the photoelectric conversion films 70r, 70g, and 70b can be suppressed.

Specially, the photoelectric conversion film 70g covers the portion 31b corresponding to the peripheral portion 611b of the conductive film 61 in the dielectric film 31 in addition to the main portion 611a of the portion corresponding to the light receiving surface 70r1 of the photoelectric conversion film 70r in the conductive film 61. In other words, the conductive film 61 and the dielectric film 31 isolate the photoelectric conversion film 70r and the photoelectric conversion film 70g from the ambient atmosphere on the peripheral side in which the photoelectric conversion films 70r and 70g do not need to be electrically in contact with the conductive film 61 between the photoelectric conversion film 70r and the photoelectric conversion film 70g. Therefore, moisture and oxygen in the ambient atmosphere do not easily enter the photoelectric conversion film 70r and the photoelectric conversion film 70g from between the photoelectric conversion film 70r and the photoelectric conversion film 70g. In the similar manner, the photoelectric conversion film 70b covers the portion 32b corresponding to the peripheral portion 621b of the conductive film 62 in the dielectric film 32 in addition to the main portion 621a of the portion corresponding to the light receiving surface 70g1 of the photoelectric conversion film 70g in the conductive film 62. Therefore, moisture and oxygen in the ambient atmosphere do not easily enter the photoelectric conversion film 70g and the photoelectric conversion film 70b from between the photoelectric conversion film 70g and the photoelectric conversion film 70b. Thus, degradation of the characteristics of the photoelectric conversion films due to ingress of moisture and oxygen from between a plurality of photoelectric conversion films can be easily suppressed.

Moreover, the solid-state imaging device 700 shown in FIG. 10A has a structure in which signals of the photoelectric conversion films 770g and 770b are transferred from the electrode films 762g and 762b to semiconductor regions 711g and 711b via contact plugs 780g and 780b. In this case, the contact plugs 780g and 780b penetrate through the photoelectric conversion films 770r and 770g and the electrode films 761g, 762g, 761r, and 762r. At this time, for example, as shown in FIG. 10E, the contact plug 780b needs to include a conductive portion 780b1 and a dielectric portion 780b2. In other words, the contact plug 780b needs to have a structure in which the side of the columnar conductive portion 780b1 is covered by the cylindrical dielectric portion 780b2 for preventing short-circuiting of the conductive portion 780b1 with the photoelectric conversion films 770r and 770g and the electrode films 761g, 762g, 761r, and 762r. The same thing can be said for the case of forming an opening in the photoelectric conversion films 770r and 770g and forming the contact plug 780b and the case of forming the contact plug 780b and then stacking the photoelectric conversion films 770r and 770g. As a result, in order to avoid attenuation of a signal to be transferred, the resistance of the conductive portion 780b1 needs to be reduced by making the cross sectional area of the conductive portion 780b1 be a predetermined value or more, so that the cross sectional area of the contact plug 780b tends to become large as a whole. Therefore, the light receiving area of the photoelectric conversion films 770r and 770g tends to be reduced.

On the contrary, in the first embodiment, the structure is such that the three photoelectric conversion films 70r, 70g, and 70b are formed above the multi-layer interconnection structure MST and signals of the photoelectric conversion films 70r, 70g, and 70b can be transferred from the electrode films 51, 52, 53, and 54 in the uppermost wiring layer 50 of the multi-layer interconnection structure MST to the semiconductor regions via the wires in the multi-layer interconnection structure MST. In other words, the electrode film 51 is covered by the photoelectric conversion film 70r and a signal of the photoelectric conversion film 70r can be transferred. The surface and the sides of the electrode film 52 are covered by the conductive film 61 connected to the photoelectric conversion films 70r and 70g. The surface and the sides of the electrode film 53 are covered by the conductive film 62 connected to the photoelectric conversion films 70g and 70b. The surface and the sides of the electrode film 54 are covered by the conductive film 63 connected to the photoelectric conversion film 70b. At this time, the conductive film 61 and the conductive film 62 are insulated from each other via the dielectric film 31, and the conductive film 62 and the conductive film 63 are insulated from each other via the dielectric film 32. Consequently, signals of the photoelectric conversion films 70r, 70g, and 70b can be easily transferred to the semiconductor regions without using contact plugs penetrating through the photoelectric conversion films 70r, 70g, and 70b. Moreover, even if the area of the electrode films 52, 53, and 54 is made small, the contact area with the conductive films 61, 62, and 63 is easily secured, so that attenuation of a signal to be transferred can be easily avoided. As a result, reduction of the light receiving area of the photoelectric conversion films 70r, 70g, and 70b can be suppressed.

Alternatively, consider a case where the photoelectric conversion films 770r, 770g, and 770b are formed of an organic material in the solid-state imaging device 700 shown in FIG. 10A. In this case, in order to form the contact plug 780b that electrically connects the electrode film 762b and the semiconductor region 711b for collecting charges of the uppermost (third) photoelectric conversion film 770b, a contact hole that penetrates through the first photoelectric conversion film 770r and the second photoelectric conversion film 770g and exposes the surface of the semiconductor region 711b needs to be formed (see FIG. 10B to FIG. 10E). At this time, because both the first photoelectric conversion film 770r and the second photoelectric conversion film 770g are organic films, micro-patterning is difficult to perform, so that size shrinkage of the through hole is difficult. Moreover, for example, if etching processing of the photoelectric conversion film 770r and the photoelectric conversion film 770g is performed by using gas, the photoelectric conversion film 770r and the photoelectric conversion film 770g are exposed to the gas for etching, so that the characteristics of the photoelectric conversion film 770r and the photoelectric conversion film 770g tends to degrade. If cleaning processing is performed with chemical solutions when removing resist for patterning, the photoelectric conversion film 770r and the photoelectric conversion film 770g are immersed in the chemical solutions, so that the characteristics of the photoelectric conversion film 770r and the photoelectric conversion film 770g tend to degrade.

On the contrary, in the first embodiment, as described above, because signals of the photoelectric conversion films 70r, 70g, and 70b are transferred to the semiconductor regions without using contact plugs penetrating through the photoelectric conversion films 70r, 70g, and 70b, a contact hole that penetrate through the photoelectric conversion films 70r, 70g, and 70b need not be formed. Moreover, the photoelectric conversion films 70r and 70g are patterns with a dimension equal to or larger than a lower limit capable of being formed by vapor deposition using a metal mask, so that they can be formed by performing patterning by plating or vapor deposition using a metal mask. Moreover, it is not needed to perform etching processing of the photoelectric conversion film 770r and the photoelectric conversion film 770g and cleaning processing for removing resist, so that degradation of the characteristics of the photoelectric conversion films 70r and 70g can be suppressed in terms thereof.

Alternatively, consider a case where in manufacturing the solid-state imaging device 700 shown in FIG. 10A, every time a film such as a dielectric film is formed, a hole is formed in the film by using resist and a dry etching method or the like and tungsten is embedded in the hole to extend a contact plug upward. In this case, the width of each hole needs to be made large by the length corresponding to a process margin considering misalignment of upper and lower holes. Therefore, for example, the cross-sectional area of the contact plug 780b becomes large as a whole, so that the light receiving area of the photoelectric conversion films 770r and 770g tends to be reduced.

On the contrary, in the first embodiment, as described above, signals of the photoelectric conversion films 70r, 70g, and 70b are easily transferred to semiconductor regions without using contact plugs penetrating through the photoelectric conversion films 70r, 70g, and 70b. Moreover, even if the area of the electrode films 52, 53, and 54 is made small, the contact area with the conductive films 61, 62, and 63 is easily secured, so that attenuation of a signal to be transferred can be avoided. As a result, reduction of the light receiving area of the photoelectric conversion films 70r, 70g, and 70b can be suppressed.

It should be noted that the order of stacking the photoelectric conversion films 70r, 70g, and 70b that perform photoelectric conversion by absorbing light in wavelength regions of red, green, and blue is not limited to the order shown in FIG. 1A and any other order can be employed.

Moreover, the photoelectric conversion films 70r, 70g, and 70b can be formed of composite semiconductors having properties of performing photoelectric conversion by absorbing light in wavelength regions of red, green, and blue, respectively. For example, the photoelectric conversion films 70r, 70g, and 70b can be formed of GaN in which the composition ratio of Ga/N is adjusted so that photoelectric conversion is performed by absorbing light in wavelength regions of red, green, and blue, respectively. Alternatively, for example, the photoelectric conversion films 70r, 70g, and 70b can be formed of AlₓGa₁₋ₓN in which the composition ratio x of Al/Ga is adjusted so that photoelectric conversion is performed by absorbing light in wavelength regions of red, green, and blue, respectively. In this case, the band gap energy of AlₓGa₁₋ₓN can be adjusted to become large by making the composition ratio x in AlₓGa₁₋ₓN large and thus the absorption wavelength of AlₓGa₁₋ₓN can be adjusted to become short (red→green→blue).

Furthermore, the electrode film 51, the electrode film 52, the electrode film 53, the electrode film 54, and the structure formed thereabove (see FIG. 1A) can be formed on a back surface 10b (see FIG. 1A) side of the semiconductor substrate 10 instead of being formed on the multi-layer interconnection structure MST. In other words, the solid-state imaging device can be a back-illuminated solid-state imaging device. The semiconductor substrate in this case, for example, can be obtained by preparing an SOI substrate and polishing the back surface of the SOI substrate until an embedded oxide layer is exposed. Then, for example, a contact plug that connects each electrode film with a semiconductor region is formed by forming a contact hole that exposes the back surface of the semiconductor region in the semiconductor substrate at a position corresponding to each electrode film and embedding a conductive material. In this manner, a back-side illumination solid-state imaging device can be formed.

### Second Embodiment

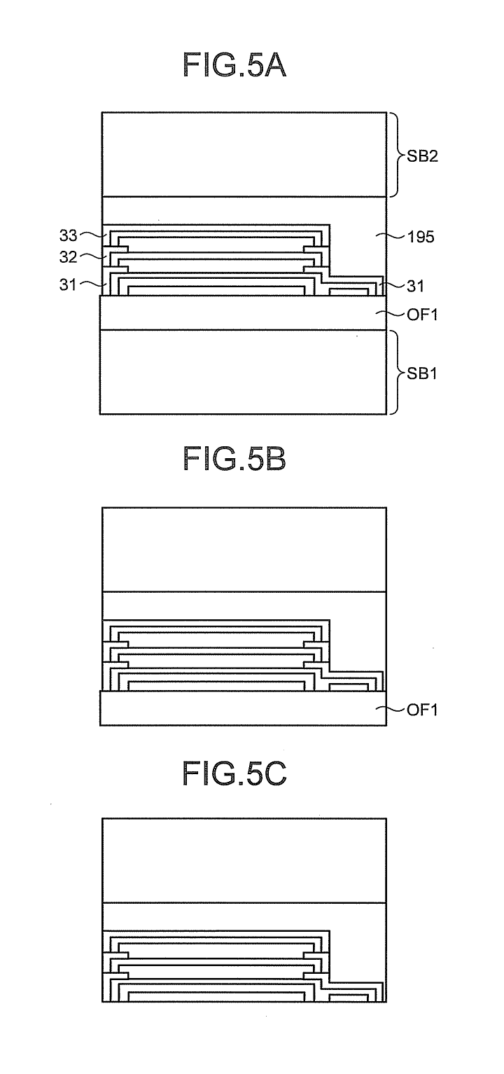

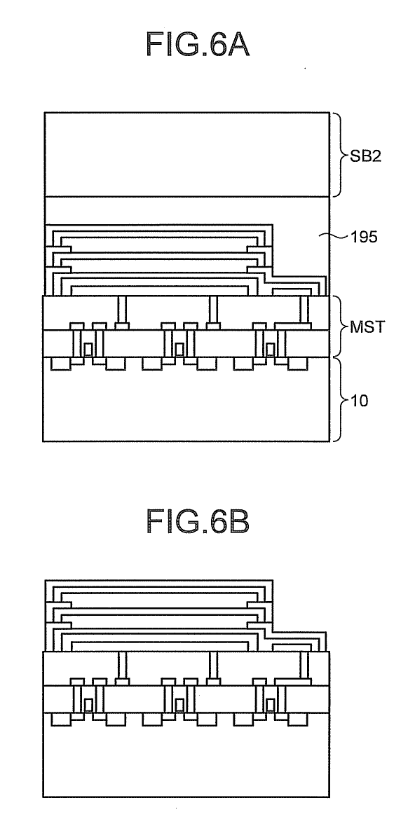

Next, the manufacturing method of the solid-state imaging device 1 according to the second embodiment is explained with reference to FIG. 5A to FIG. 5C, FIG. 6A, and FIG. 6B. FIG. 5A to FIG. 5C, FIG. 6A, and FIG. 6B are process cross-sectional views illustrating the manufacturing method of the solid-state imaging device 1. In the following, a portion different from the first embodiment is mainly explained.

In the process shown in FIG. 5A, an oxide film OF1 is formed on a semiconductor substrate SB1 by the CVD method or a thermal process. Then, patterns similar to the electrode film 51, the electrode film 52, the electrode film 53, and the electrode film 54 in the first embodiment are formed on the oxide film OF1. Thereafter, in the similar manner to the first embodiment, the structure in which the photoelectric conversion films 70r, 70g, and 70b are sequentially stacked is formed. Then, adhesive 195 is applied to cover the exposed surfaces of the dielectric films 31, 32, and 33 and another semiconductor substrate SB2 is adhered thereto.

In the process shown in FIG. 5B, the semiconductor substrate SB1 used as a support substrate is removed by a dry etching or a wet etching. At this time, the oxide film OF1 functions as an etching stopper.

In the process shown in FIG. 5C, the oxide film OF1 is removed by a dry etching or a wet etching. At this time, the electrode film 51, the electrode film 52, the electrode film 53, and the electrode film 54 are exposed, however, patterning is performed by using a lithography so that the photoelectric conversion film 70r is not exposed.

In the process shown in FIG. 6A, the electrode film 51, the electrode film 52, the electrode film 53, and the electrode film 54 in the multi-layer interconnection structure MST formed on the semiconductor substrate 10 are bonded to the contact plug 83, the contact plug 82, a contact plug (not shown), and a contact plug (not shown) corresponding thereto in the similar manner to the first embodiment.

In the process shown in FIG. 6B, the semiconductor substrate SB2 and the adhesive 195 are removed by a dry etching or a wet etching.

### Third Embodiment

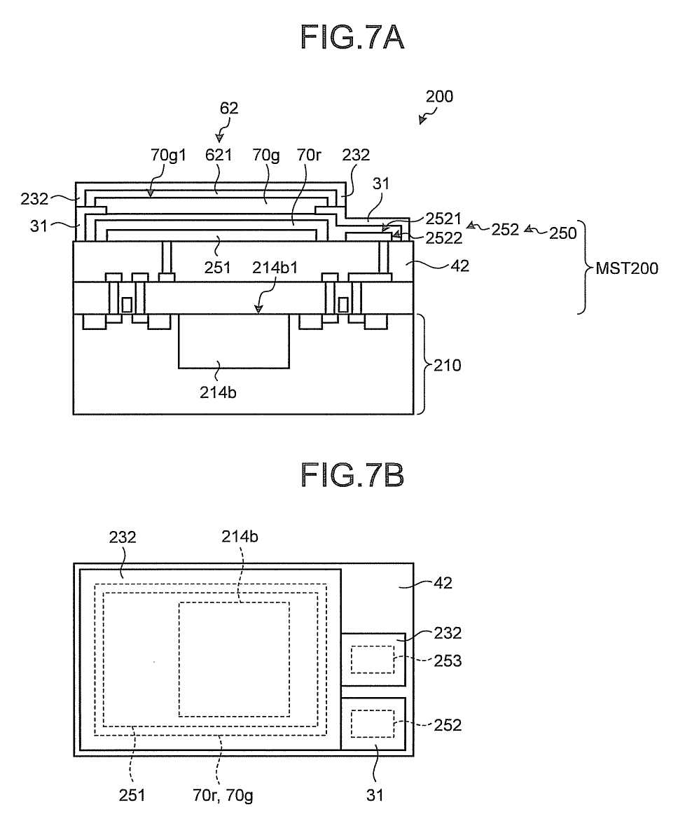

Next, a solid-state imaging device 200 according to the third embodiment is explained with reference to FIG. 7A and FIG. 7B. FIG. 7A is a cross-sectional view illustrating a cross sectional configuration of the solid-state imaging device 200. FIG. 7B is a plan view illustrating a layout configuration of the solid-state imaging device 200. In the following, a portion different from the first embodiment is mainly explained.

The solid-state imaging device 200 includes a semiconductor substrate 210, a multi-layer interconnection structure MST200, and a dielectric film (second dielectric film) 232.

In the solid-state imaging device 200, two layers of the photoelectric conversion films 70r and 70g are sequentially stacked on the multi-layer interconnection structure MST200 and a photoelectric conversion portion 214b is arranged in the well region 13 of the semiconductor substrate 210 instead of the remaining one layer of the photoelectric conversion film 70b (see FIG. 1A). The photoelectric conversion portion 214b is arranged in the semiconductor substrate 210 so that light that has passed through the photoelectric conversion films 70g and 70r enters. In other words, the photoelectric conversion portion 214b has a pattern included in the photoelectric conversion films 70r and 70g when visualized from a direction vertical to a light receiving surface 214b1 of the photoelectric conversion portion 214b (see FIG. 7B). Put another way, the photoelectric conversion portion 214b uses the photoelectric conversion films 70r and 70g as a color filter. The photoelectric conversion portion 214b generates charges corresponding to light entered via the photoelectric conversion films 70r and 70g and stores them.

The photoelectric conversion portion 214b is, for example, a photodiode. The photoelectric conversion portion 214b, for example, includes a charge storage region. The charge storage region is formed of semiconductor (for example, silicon) that contains second conductivity-type (for example, N-type) impurities at a concentration higher than the concentration of the first conductivity-type impurities in the well region 13. The N-type impurities are phosphorus or arsenic, for example.

For example, when the photoelectric conversion film 70g is formed of an organic material that absorbs light in the green wavelength region and transmits light in other wavelength regions, and the photoelectric conversion film 70r is formed of an organic material that absorbs light in the red wavelength region and transmits light in other wavelength regions, light in the blue wavelength region mainly enters the photoelectric conversion portion 214b. Therefore, a signal corresponding to charges generated in the photoelectric conversion portion 214b can be used as a signal for blue. In other words, photoelectric conversion for red and green is performed in the photoelectric conversion films and photoelectric conversion for blue is performed in the photoelectric conversion portion 214b.

In the photoelectric conversion portion 214b, for example, white light that has passed through regions, such as regions in which electrode films 252 and 253 are formed, may enter, however, signals for red and green are obtained, so that a signal for blue can be derived by removing the signals for red and green from the signal obtained in the photoelectric conversion portion 214b by data processing without forming a filter for blue.

The uppermost wiring layer 250 in the multi-layer interconnection structure MST200, for example, includes an electrode film (first electrode film) 251, an electrode film (second electrode film) 252, and an electrode film (third electrode film) 253. The electrode film 251, the electrode film 252, and the electrode film 253 are separated from each other in the wiring layer 250 (see FIG. 73). The electrode film 251, the electrode film 252, and the electrode film 253 are formed of, for example, a transparent conductive material such as ITO, TiO₂, MgO, or ZnO so that incident light transmits toward the photoelectric conversion portion 214b.

The dielectric film 232 covers the whole of the portion 621 corresponding to the light receiving surface 70g1 of the photoelectric conversion film 70g in the conductive film 62.

The manufacturing method of the solid-state imaging device 200 is different from the first embodiment in the following points.

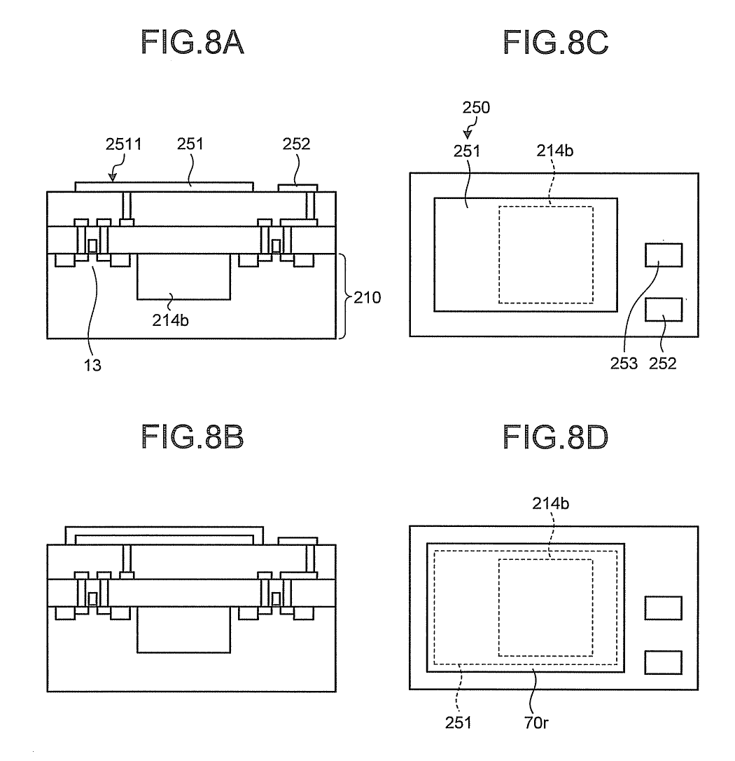

In the process shown in FIG. 8A and FIG. 8C, processing basically similar to the process shown in FIG. 2A and FIG. 2D is performed, however, processing different from the process shown in FIG. 2A and FIG. 2D is performed in the following points.

The photoelectric conversion portion 214b is formed in the well region 13 of the semiconductor substrate 210 by an ion implantation method or the like. The photoelectric conversion portion 214b, for example, includes a charge storage region. The charge storage region is formed, for example, by implanting the second conductivity-type (for example, N-type) impurities in the well region 13 of the semiconductor substrate 210 at a concentration higher than the concentration of the first conductivity-type impurities in the well region 13.

Moreover, a conductive layer (not shown) is formed on the entire surface by a sputtering method or the like. The conductive layer is, for example, formed of a transparent conductive material such as ITO, TiO₂, MgO, or ZnO. The conductive layer is patterned by a lithography and an etching to form the wiring layer 250 including the electrode film 251, the electrode film 252, and the electrode film 253. The electrode film 251 is formed of a pattern that is to be included in the photoelectric conversion film 70r and includes the photoelectric conversion portion 214b when visualized from a direction vertical to a surface 2511 of the electrode film 251.

In the process shown in FIG. 8B and FIG. 8D, processing basically similar to the process shown in FIG. 2B and FIG. 2E is performed, however, processing different from the process shown in FIG. 2B and FIG. 2E is performed in the following points.

The photoelectric conversion film 70r is formed of a pattern that includes the electrode film 251 and includes the photoelectric conversion portion 214b when visualized from a direction vertical to the surface 2511 of the electrode film 251 (see FIG. 8D).

Thereafter, processing similar to that from the process shown in FIG. 2C and FIG. 2F to the process shown in FIG. 3C and FIG. 3F is performed.

In the process shown in FIG. 7A and FIG. 7B, processing basically similar to the process shown in FIG. 4A and FIG. 4D is performed, however, processing different from the process shown in FIG. 4A and FIG. 4D is performed in the following points.

The dielectric film 232 is formed of a pattern that includes the conductive film 62 when visualized from a direction vertical to the light receiving surface 70g1 of the photoelectric conversion film 70g (see FIG. 1B). Therefore, the dielectric film 232 covers the whole of the portion 621 corresponding to the light receiving surface 70g1 of the photoelectric conversion film 70g in the conductive film 62.

### Fourth Embodiment

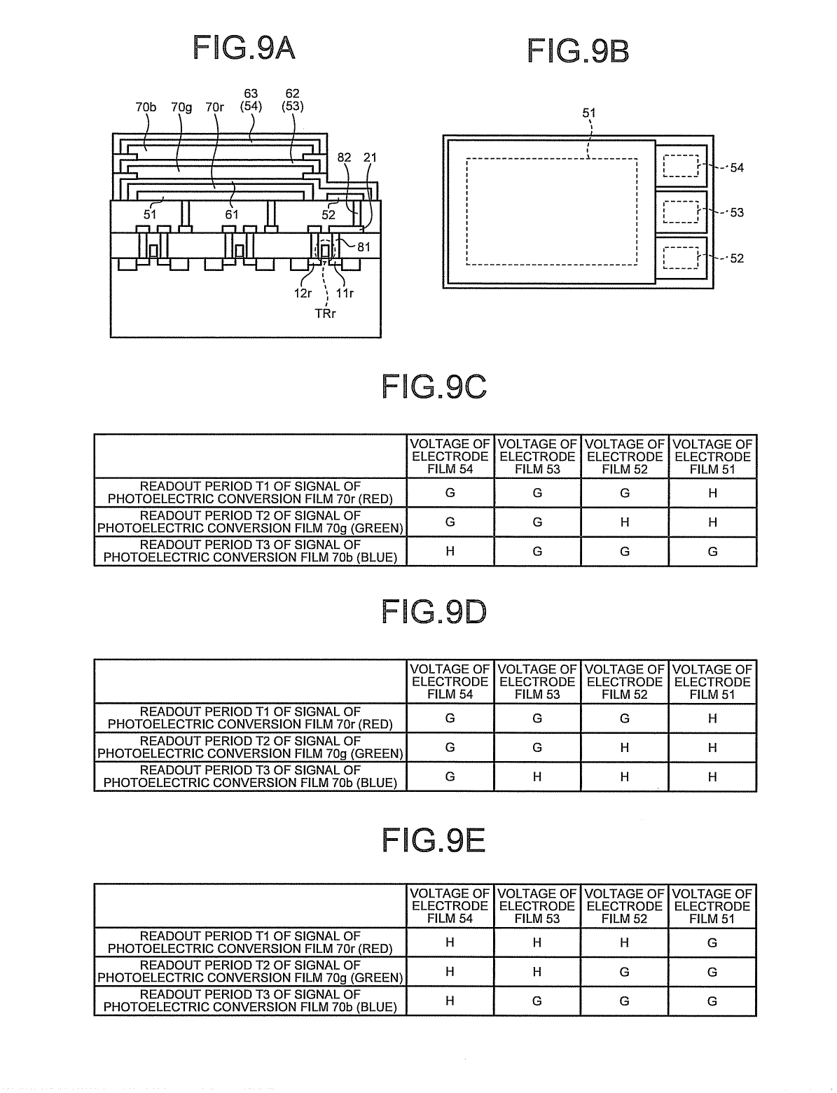

Next, the operation of the solid-state imaging device 1 according to the fourth embodiment is explained with reference to FIG. 9A to FIG. 9E. In the following, a portion different from the first embodiment is mainly explained.

In the solid-state imaging device 1, as shown in FIG. 9A, when a bias is applied to one of the electrode film 51 and the electrode film 52, a signal corresponding to charges generated in the photoelectric conversion film 70r is read out from the other of the electrode film 51 and the electrode film 52. When a bias is applied to one of the electrode film 52 and the electrode film 53, a signal corresponding to charges generated in the photoelectric conversion film 70g is read out from the other of the electrode film 52 and the electrode film 53. When a bias is applied to one of the electrode film 53 and the electrode film 54, a signal corresponding to charges generated in the photoelectric conversion film 70b is read out from the other of the electrode film 53 and the electrode film 54.

Specifically, for example, when charges to be read out are electrons, a ground voltage G is applied to the electrode film 51 as a bias via a ground line in the solid-state imaging device 1 from an external power circuit. Consequently, the ground voltage G is applied to the surface on the opposite side of the light receiving surface of the photoelectric conversion film 70r. On the other hand, the electrode film 52 on the side on which a signal is to be read out is connected to the semiconductor region 11r in the semiconductor substrate 10 via wires (for example, the contact plug 82, the electrode film 21, and the contact plug 81) in the multi-layer interconnection structure MST. When the transfer transistor TRr is off, the semiconductor region 12r in the non-conducting state with the semiconductor region 11r is reset to a power-supply voltage H by a not-shown reset transistor. Thereafter, when the reset transistor is turned off and the transfer transistor TRr is turned on, this power-supply voltage H is applied to the light receiving surface of the photoelectric conversion film 70r via the semiconductor region 11r, the contact plug 81, the electrode film 21, the contact plug 82, the electrode film 52, and the conductive film 61. In other words, an electric field in accordance with the difference between the ground voltage G and the power-supply voltage H is applied to both surfaces of the photoelectric conversion film 70r, and a signal corresponding to charges generated in the photoelectric conversion film 70r is read out in the similar manner to the first embodiment.

The electrode film 52 functions both as an electrode on the light receiving surface 70r1 side of the photoelectric conversion film 70r and as an electrode on the surface 70g3 side of the photoelectric conversion film 70g are shared. The electrode film 53 functions both as an electrode on the light receiving surface 70g1 side of the photoelectric conversion film 70g and as an electrode on the surface 70b3 side of the photoelectric conversion film 70b. Therefore, an operational contrivance is needed when reading out a signal of each of the photoelectric conversion films 70r, 70g, and 70b. For example, as shown in FIG. 9C to FIG. 9E, readout periods T1, T2, and T3 of signals of the photoelectric conversion films 70r, 70g, and 70b are set in a predetermined order so as not to overlap with each other.

For example, in the case where signals need to be read out in the order of the readout periods T1, T2, and T3 at high speed (for example, in the case where the solid-state imaging device 1 operates in a high-speed operation mode), when changing a voltage to be applied to a predetermined electrode film of the electrode films 51, 52, 53, and 54 for reading out each of the signals of the photoelectric conversion films 70r, 70g, and 70b, the operation of changing from the power-supply voltage (second voltage) H to the ground voltage (first voltage) G is performed without performing the operation of changing from the ground voltage G to the power-supply voltage H. For example, the readout operation shown in FIG. 9E is performed. For example, when each of the photoelectric conversion films 70r, 70g, and 70b is formed of an organic material, the power-supply voltage H (for example, 10 V or more) higher than a power-supply voltage for other operations in the solid-state imaging device 1 is often needed for signal readout, so that a step-up circuit is needed. With this circuit, for example, the time required to lower the voltage from the power-supply voltage H to the ground voltage G (for example, 0 V) becomes shorter than the time required to raise the voltage from the ground voltage G to the power-supply voltage H. In view of this point, the readout operation shown in FIG. 9E is proposed as a method of readout at high speed taking the readout order into consideration.

In the period T1, when the electrode film 51 is set to the ground voltage G and the electrode films 52 to 54 are set to the power-supply voltage H, the potential difference occurs between both surfaces (between the light receiving surface and the surface opposite thereto) of the photoelectric conversion film 70r (for example, for red), so that a signal of the photoelectric conversion film 70r can be read out. Next, in the period T2, when the electrode film 52 is set to the ground voltage G, the potential difference occurs between both surfaces of the photoelectric conversion film 70g (for example, for green), so that a signal of the photoelectric conversion film 70g can be read out. Furthermore, in the period T3, when the electrode film 53 is set to the ground voltage G, the potential difference occurs between both surfaces of the photoelectric conversion film 70b (for example, for blue), so that a signal of the photoelectric conversion film 70b can be read out. When reading out the signals in the readout operation shown in FIG. 9E in this manner, in the periods T2 and T3, the operation of lowering the voltage from the power-supply voltage H to the ground voltage G is performed without performing the operation of raising the voltage from the ground voltage G to the power-supply voltage H, so that the length of the periods T2 and T3 can be shortened, enabling to perform the readout operation at high speed as a whole.

It should be noted that, when signals need to be read out at high speed in the order of the periods T3, T2, and T1, the readout operation shown in FIG. 9D can be performed.

Alternatively, for example, in the case where signals need to be read out with low power consumption in the order of the periods T1, T2, and T3 (for example, in the case where the solid-state imaging device 1 operates in a low power-consumption operation mode), when reading out each of the signals of the photoelectric conversion films 70r, 70g, and 70b, the solid-state imaging device 1 is controlled to maintain the state where the power-supply voltage (second voltage) H is applied to at least one electrode film while applying the ground voltage (first voltage) G to two or more electrode films of the electrode films 51, 52, 53, and 54. For example, the readout operation shown in FIG. 9C is performed. In other words, from a power consumption viewpoint, the number of voltage raised states is preferably small. Thus, the readout operation shown in FIG. 9C is proposed as a method of readout with low power consumption.

In the period T1, when the electrode film Si is set to the power-supply voltage H and the electrode films 52 to 54 are set to the ground voltage G, the potential difference occurs between both surfaces (between the light receiving surface and the surface opposite thereto) of the photoelectric conversion film 70r (for example, for red), so that a signal of the photoelectric conversion film 70r can be read out. Next, in the period T2, when the electrode film 52 is set to the power-supply voltage H, the potential difference occurs between both surfaces of the photoelectric conversion film 70g (for example, for green), so that a signal of the photoelectric conversion film 70g can be read out. Furthermore, in the period T3, when the electrode films 51 and 52 are set to the ground voltage G and the electrode film 54 is set to the power-supply voltage H, the potential difference occurs between both surfaces of the photoelectric conversion film 70b (for example, for blue), so that a signal of the photoelectric conversion film 70b can be read out. When reading out the signals in the readout operation shown in FIG. 9C in this manner, in the periods T1 and T3, one electrode film is in the high voltage state (state where the power-supply voltage H is applied) and remaining electrode films are in the low voltage state (state where the ground voltage G is applied), and in the period T2, two electrode films are in the high voltage state and a remaining electrode film is in the low voltage state. In other words, in any period, minimum necessary number of high voltage states is used for applying an electric field between both surfaces of a photoelectric conversion film as a readout target without applying an electric field between both surfaces of photoelectric conversion films other than the readout target, so that the power consumption by the readout operation can be reduced by this readout operation.

It should be noted that the readout operation shown in FIG. 9C can be performed even when it is needed to perform the readout operation of signals with low power consumption in the order (for example, in the order of the periods T3, T2, and T1, or in the order of the periods T2, T1, and T3) reordered from the order of the periods T1, T2, and T3. Alternatively, when performing the readout operation shown in FIG. 9C, in the period T2, the electrode films 51 and 52 can be set to the power-supply voltage H and the electrode films 53 and 54 can be set to the ground voltage G.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a first electrode film;
a first photoelectric conversion film that covers a surface and a side of the first electrode film;
a first conductive film that covers a light receiving surface and a side of the first photoelectric conversion film;
a dielectric film that covers a portion corresponding to the side of the first photoelectric conversion film in the first conductive film;
a second photoelectric conversion film that covers a main portion of a portion corresponding to the light receiving surface of the first photoelectric conversion film in the first conductive film; and
a second conductive film that covers a light receiving surface and a side of the second photoelectric conversion film.

2. The solid-state imaging device according to claim 1, wherein
the dielectric film includes an opening corresponding to the main portion of the first conductive film, and
the second photoelectric conversion film covers the main portion of the first conductive film via the opening of the dielectric film.

3. The solid-state imaging device according to claim 1, wherein
the first conductive film has a pattern including the first photoelectric conversion film when visualized from a direction vertical to the light receiving surface of the first photoelectric conversion film, and
the second conductive film has a pattern including the second photoelectric conversion film when visualized from a direction vertical to the light receiving surface of the second photoelectric conversion film.

4. The solid-state imaging device according to claim 3, wherein the dielectric film has a pattern including the first conductive film when visualized from a direction vertical to the light receiving surface of the first photoelectric conversion film.

5. The solid-state imaging device according to claim 1, wherein
the dielectric film further covers a peripheral portion positioned around the main portion in the portion corresponding to the light receiving surface of the first photoelectric conversion film in the first conductive film, and
the second photoelectric conversion film further covers a portion corresponding to the peripheral portion in the dielectric film.

6. The solid-state imaging device according to claim 5, further comprising a second dielectric film that covers a portion corresponding to the side of the second photoelectric conversion film in the second conductive film.

7. The solid-state imaging device according to claim 6, wherein the second dielectric film further covers a peripheral portion positioned around a main portion in a portion corresponding to the light receiving surface of the second photoelectric conversion film in the second conductive film.

8. The solid-state imaging device according to claim 1, further comprising:
a dielectric layer whose surface is partially covered by the first electrode film and the first photoelectric conversion film;
a second electrode film that covers a surface of the dielectric layer at a position adjacent to the first electrode film and the first photoelectric conversion film; and
a third electrode film that covers a surface of the dielectric layer at a position adjacent to the first electrode film, the first photoelectric conversion film, and the second electrode film, wherein
the first conductive film covers the second electrode film,
the second conductive film covers the third electrode film, and
the dielectric film covers the first conductive film and is covered by the second conductive film to insulate the first conductive film and the second conductive film from each other.

9. The solid-state imaging device according to claim 8, wherein
the first conductive film has a pattern including the first electrode film, the first photoelectric conversion film, and the second electrode film when visualized from a direction vertical to the light receiving surface of the first photoelectric conversion film, and
the second conductive film includes a pattern including the second photoelectric conversion film and the third electrode film when visualized from a direction vertical to the light receiving surface of the first photoelectric conversion film.

10. The solid-state imaging device according to claim 1, further comprising:
a second dielectric film that covers a portion corresponding to the side of the second photoelectric conversion film in the second conductive film;
a third photoelectric conversion film that covers a main portion of a portion corresponding to the light receiving surface of the second photoelectric conversion film in the second conductive film; and
a third conductive film that covers a light receiving surface and a side of the third photoelectric conversion film.

11. The solid-state imaging device according to claim 10, further comprising:
a dielectric layer whose surface is partially covered by the first electrode film and the first photoelectric conversion film; and
a fourth electrode film that covers a surface of the dielectric layer at a position adjacent to the first electrode film, the first photoelectric conversion film, and the third electrode film, and is covered by the third conductive film, wherein
the third conductive film covers the fourth electrode film, and
the second dielectric film covers the second conductive film and is covered by the third conductive film to insulate the second conductive film and the third conductive film from each other.

12. The solid-state imaging device according to claim 11, wherein the third conductive film has a pattern including the third photoelectric conversion film and the fourth electrode film when visualized from a direction vertical to the light receiving surface of the third photoelectric conversion film.

13. The solid-state imaging device according to claim 11, wherein the solid-state imaging device performs an operation of changing to a first voltage from a second voltage higher than the first voltage without performing an operation of changing from the first voltage to the second voltage, when changing a voltage applied to a predetermined electrode film among the first electrode film, the second electrode film, the third electrode film, and the fourth electrode film for reading out each of a signal of the first photoelectric conversion film, a signal of the second photoelectric conversion film, and a signal of the third photoelectric conversion film.

14. The solid-state imaging device according to claim 13, wherein
the solid-state imaging device reads out
the signal of the first photoelectric conversion film by applying a ground voltage to the first electrode film and applying a power-supply voltage to the second electrode film, the third electrode film, and the fourth electrode film,
the signal of the second photoelectric conversion film by changing a voltage applied to the second electrode film from the power-supply voltage to the ground voltage, and
the signal of the third photoelectric conversion film by changing a voltage applied to the third electrode film from the power-supply voltage to the ground voltage.

15. The solid-state imaging device according to claim 13, wherein
the solid-state imaging device reads out
the signal of the third photoelectric conversion film by applying a ground voltage to the fourth electrode film and applying a power-supply voltage to the first electrode film, the second electrode film, and the third electrode film,
the signal of the second photoelectric conversion film by changing a voltage applied to the third electrode film from the power-supply voltage to the ground voltage, and
the signal of the first photoelectric conversion film by changing a voltage applied to the second electrode film from the power-supply voltage to the ground voltage.

16. The solid-state imaging device according to claim 11, wherein the solid-state imaging device maintains a state where a first voltage is applied to at least two of the first electrode film, the second electrode film, the third electrode film, and the fourth electrode film while a second voltage higher than the first voltage is applied to at least one of the first electrode film, the second electrode film, the third electrode film, and the fourth electrode film, when reading out each of a signal of the first photoelectric conversion film, a signal of the second photoelectric conversion film, and a signal of the third photoelectric conversion film.

17. The solid-state imaging device according to claim 16, wherein the solid-state imaging device performs a first operation of reading out the signal of the first photoelectric conversion film by applying a power-supply voltage to the first electrode film and applying a ground voltage to the second electrode film, the third electrode film, and the fourth electrode film, a second operation of reading out the signal of the second photoelectric conversion film by applying the power-supply voltage to the first electrode film and the second electrode film and applying the ground voltage to the third electrode film and the fourth electrode film, and a third operation of reading out the signal of the third photoelectric conversion film by applying the power-supply voltage to the fourth electrode film and applying the ground voltage to the first electrode film, the second electrode film, and the third electrode film, in different periods.

18. The solid-state imaging device according to claim 16, wherein the solid-state imaging device performs a first operation of reading out the signal of the first photoelectric conversion film by applying a power-supply voltage to the first electrode film and applying a ground voltage to the second electrode film, the third electrode film, and the fourth electrode film, a third operation of reading out the signal of the third photoelectric conversion film by applying the power-supply voltage to the fourth electrode film and applying the ground voltage to the first electrode film, the second electrode film, and the third electrode film, and a fourth operation of reading out the signal of the second photoelectric conversion film by applying the ground voltage to the first electrode film and the second electrode film and applying the power-supply voltage to the third electrode film and the fourth electrode film, in different periods.

19. The solid-state imaging device according to claim 1, further comprising a photoelectric conversion portion that is arranged in a semiconductor substrate so that light that passed through the first photoelectric conversion film and the second photoelectric conversion film enters.

20. The solid-state imaging device according to claim 19, wherein
the first photoelectric conversion film has a pattern including the photoelectric conversion portion when visualized from a direction vertical to the light receiving surface of the first photoelectric conversion film, and
the second photoelectric conversion film has a pattern including the photoelectric conversion portion when visualized from a direction vertical to the light receiving surface of the second photoelectric conversion film.
